(19) United States
(12) Patent Application Publication
(10) Pub. No.: US 2005/0130076 A1
(43) Pub. Date: Jun. 16, 2005

(54) Method for producing a hard mask in a capacitor device and a hard mask for use in a capacitor device

(76) Inventor: Haoren Zhuang, Wallkill, NY (US)

Correspondence Address: FISH & RICHARDSON, PC, 12390 EL CAMINO REAL, SAN DIEGO, CA, 92130-2081, US

(21) Appl. No.: 10/734,749

(22) Filed: Dec. 11, 2003

(51) Int. Cl. G03F 7/00

(52) U.S. Cl. 430/322; 430/320; 430/330

(57) ABSTRACT

A method for producing a hard mask and a hard mask for use in a capacitor device comprises the steps of applying a photosensitive sol-gel layer to the capacitor device, applying a pattern to the sol-gel layer to form a patterned layer and applying a thermal decomposition treatment to the patterned layer to convert it to a hard mask layer.

### FIELD OF THE INVENTION

The present invention relates to a method for producing a hard mask for a capacitor device and a hard mask for use in a capacitor device.

### BACKGROUND OF THE INVENTION

A conventional ferroelectric capacitor includes one or more ferroelectric layers sandwiched between a bottom electrode and a top electrode. In the production of such capacitors it is necessary to etch the top and bottom electrodes. This may be achieved using a one-step etching process in which the etching extends from the top electrode to the bottom electrode, or a two-step etching process in which the top and bottom electrodes are etched in separate processes. In each case, a hard mask is used to define the etch pattern. Normally, after etching, the remainder of the hard mask is left in situ and further layers are deposited over the remnants of the hard mask, as required, and these remnants and layers are incorporated into the final device.

The conventional processes for the production of the hard mask in FeRAM capacitors typically include at least five steps before the etching process may be initiated. Firstly, a hard mask layer, of, for example, tetraethyl orthosilicate (TEOS) is applied to the device to be etched. Next, a resist layer is applied to the hard mask layer using a spin coating technique. The etching pattern is then applied to the resist layer using a photolithographic process. The hard mask is then subjected to a reactive ion etch, according to the applied pattern. Next, the resist layer is removed. The main etching process may then commence.

Conventional methods of the type described above have a number of disadvantages, for example, there are many process steps involved in such methods rendering them time consuming and labour intensive. Furthermore, as the etching process also etches the hard mask TEOS layer as well as the capacitor materials, such as the dielectric layers and the metal layers, and hard mask materials such as TEOS etch at nearly the same rate as the capacitor materials, a thick hard mask TEOS layer is required to maintain the mask shape when etching down to the bottom electrode.

Also, a number of problems may arise from the typical height of conventional ferroelectric capacitors (around 17600 Angstroms, about one third of which is due to the presence of the hard mask layers). Due to the height of conventional capacitors, it is difficult to include a number of such capacitors in a device where space is limited.

In view of the foregoing problems with conventional processes and devices, a need exists for an easily applied method for producing a hard mask layer requiring fewer steps and resulting in capacitors of less than conventional height, without reducing production yield and without compromising performance of the device.

### SUMMARY OF THE INVENTION

According to the present invention there is provided a method for producing a hard mask in a capacitor device comprising the steps of:

applying a photosensitive sol-gel layer to said capacitor device;

applying a pattern to said sol-gel layer to form a patterned layer; and

applying a thermal decomposition treatment to said patterned layer to convert it to a hard mask layer.

According to further aspects of the present invention there is provided a ferroelectric capacitor device and an FeRAM device etched according to the hard mask formed by the method defined above.

There is also provided a hard mask formed according to the method defined above.

In comparison to conventional processes for forming a hard mask, the number of processing steps are reduced in the methods embodying the invention. Furthermore, the methods embodying the invention are easily applied and the thickness of the hard mask layer may be reduced thereby overcoming problems associated with the height of conventional capacitor devices, without reducing production yield and without compromising performance of the device.

### BRIEF DESCRIPTION OF THE DRAWINGS

Preferred features of the present invention will now be described, by way of example, with reference to the accompanying drawings in which:

FIG. 1a is a schematic cross-section through a prior art capacitor before patterning of the hard mask;

FIG. 1b is a schematic cross-section through a prior art capacitor with a photoresist layer applied over the hard mask material;

FIG. 1c is a schematic cross-section through a prior art capacitor after the photoresist layer has been exposed to a photolithographic process;

FIG. 1d is a schematic cross-section through a prior art capacitor after the hard mask has been opened by reactive ion etching;

FIG. 1e is a schematic cross-section through a prior art capacitor after removal of the remaining resist material;

FIG. 2a is a schematic cross-section through a capacitor according to an embodiment of the present invention at a first stage of production of the hard mask;

FIG. 2b is a schematic cross-section through a capacitor according to an embodiment of the present invention at a second stage of production of the hard mask; and

FIG. 2c is a schematic cross-section through a capacitor according to an embodiment of the present invention at a third stage of production of the hard mask.

### DESCRIPTION OF PREFERRED EMBODIMENTS

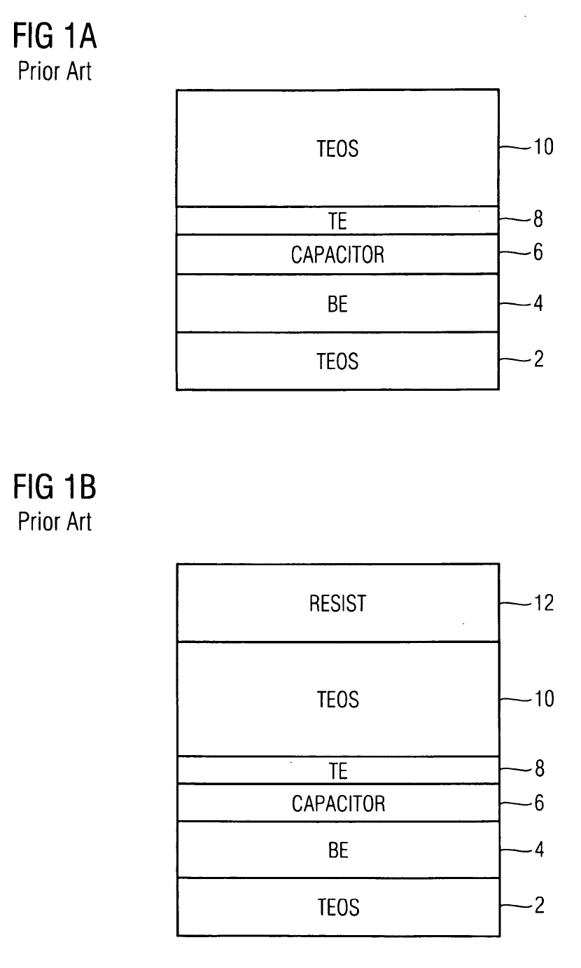

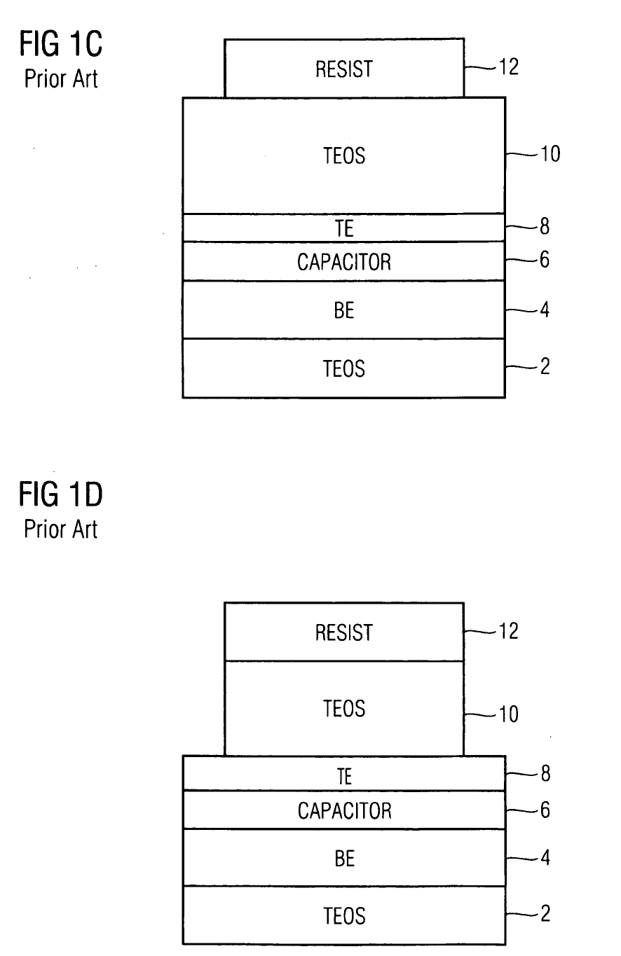

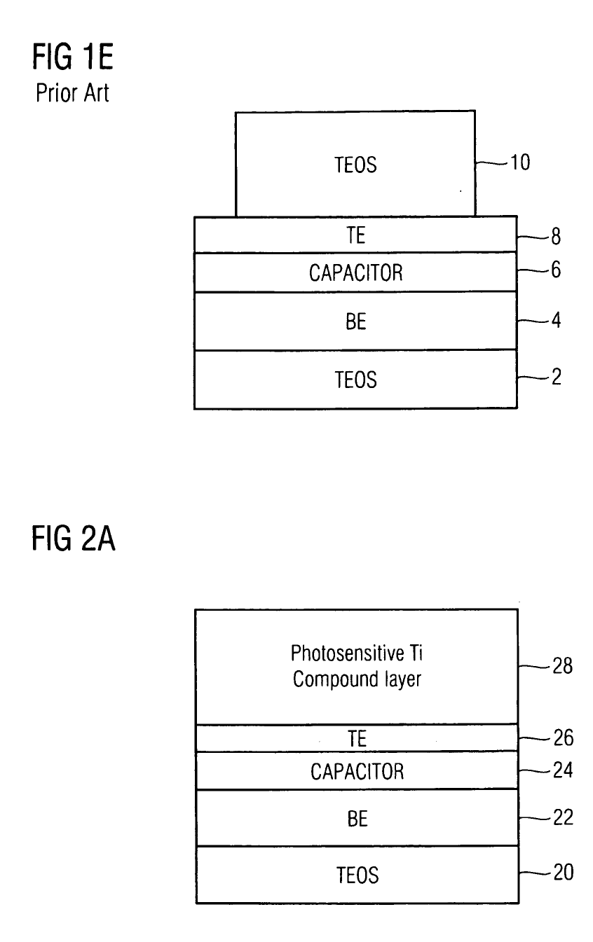

FIGS. 1a to 1e show the five stages in the conventional production process of a hard mask for an FeRam capacitor.

FIG. 1a shows a capacitor device comprising a substrate 2 onto which has been deposited a bottom electrode 4. A layer of dielectric material 6 is applied to the bottom electrode. The dielectric layer 6 is then covered by the top electrode 8. A thick layer 10 of hard mask material, such as tetraethyl orthosilicate (TEOS), is then applied over the device.

FIG. 1b shows the next stage in the process which is the application of a layer 12 of resist material to the TEOS hard mask layer 10.

FIG. 1c shows the third stage in the production process which comprises the application of the etching pattern to the resist layer 12 using a photolithographic process.

FIG. 1d shows the fourth stage in the production process. The pattern produced in the resist layer 12 is etched through the layer 10 of hard mask material to produce or ‘open’ the hard mask.

FIG. 1e shows the final stage in the production of the hard mask in which the remaining resist material has been removed.

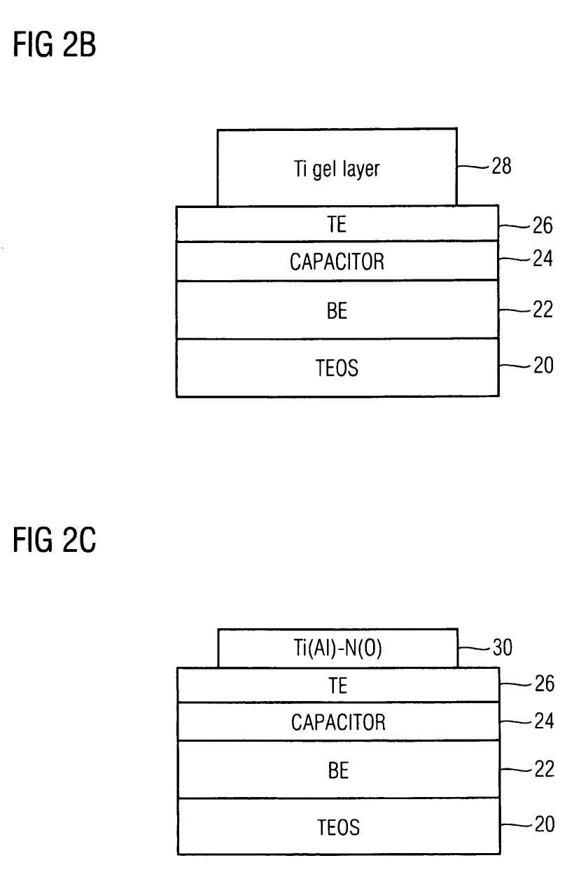

FIGS. 2a to 2c show the various stages in the production process of a hard mask in a capacitor according to a preferred embodiment of the present invention. These figures show a mask for a one-step etch from the top electrode to the bottom electrode, but the process is equally applicable to etching, in separate processes, the top and bottom electrodes.

As shown in FIG. 2a, the capacitor device comprises a substrate 20 of, for example, tetraethyl orthosilicate (TEOS) onto which has been deposited a bottom electrode 22. A layer of dielectric material 24 is applied to the bottom electrode 22 which is then covered by a top electrode layer 26.

In the first stage of production, as shown in FIG. 2a, a photosensitive organic gel layer 28 is applied to the top electrode layer 26 of the device, for example, using a spin coating technique. The photosensitive gel is a sol-gel, for example a Ti or Ti—Al organic gel.

FIG. 2b shows the next stage in the process. A pattern is applied to the gel layer 28 using, for example, a photolithographic process.

FIG. 2c shows the final stage in the production process. Using, for example, an oxygen or nitrogen thermal decomposition treatment, the patterned gel layer 28 is converted to a hard mask material 30, such as TiO2 (or TiN) or Ti—Al—O (or Al—Ti—N). The capacitor may then be etched through the thin layer of hard mask material 30.

The hard mask material formed using the above-described process may be a pure titanium compound layer or a titanium compound layer on top of TEOS, depending on the application of the device to which it is applied.

There are a number of ways in which the photosensitive Ti compound solution for use as the photosensitive gel layer 28 may be prepared. One example is to mix titanium alkoxides, such as (TiOEt)4 or Ti(OEt)4+Al(OBu)3 with ethyl acetoactate (EacAc). As the titanium compounds, such as TiO2, TiN, TiAlN, have a much higher sensitivity, that is they etch more slowly than the electrode or dielectric materials, the total thickness of the hard mask may be significantly reduced using the process embodying the present invention compared to that of conventional capacitors. Furthermore, as the remnants of the hard mask material are normally left in situ, the overall height of the final device will thereby be reduced.

In summary, the present invention provides a simplified hard mask formation process for capacitor devices such as ferroelectric capacitors or FeRAM devices. It is an easy and convenient method of patterning “exotic” hard mask materials such as TiO2, TiN, or Al2O3.

Various modifications to the embodiments of the present invention described above may be made. For example, other materials and method steps can be added or substituted for those above. Thus, although the invention has been described above using particular embodiments, many variations are possible within the scope of the claims, as will be clear to the skilled reader, without departing from the spirit and scope of the invention.

1. A method for producing a hard mask in a capacitor device comprising the steps of:
applying a photosensitive sol-gel layer to said capacitor device;
applying a pattern to said sol-gel layer to form a patterned layer; and
applying a thermal decomposition treatment to said patterned layer to convert it to a hard mask layer.

2. A method according to claim 1, further comprising the step of etching said hard mask layer according to said pattern to provide a pattern for the etching of one or more layers in said capacitor device.

3. A method according to claim 1, wherein the step of applying said photosensitive sol-gel layer comprises applying a titanium organic gel layer.

4. A method according to claim 1, wherein the step of applying said photosensitive sol-gel layer comprises applying a titanium-aluminium organic gel layer.

5. A method according to claim 1, wherein the step of applying said photosensitive sol-gel layer comprises applying a mixture of one or more titanium alkoxides with ethyl acetoactate (EacAc).

6. A method according to claim 5, wherein the step of applying said photosensitive sol-gel layer comprises applying a mixture of one or more of (TiOEt)4 or Ti(OEt)4 plus Al(OBu)3 with ethyl acetoactate (EacAc).

7. A method according to claim 1, wherein the step of applying a pattern comprises applying said pattern using a photolithographic process.

8. A method according to claim 1, wherein the step of applying a thermal decomposition treatment comprises applying an oxygen thermal decomposition treatment to convert said patterned layer to a hard mask material.

9. A method according to claim 8, wherein the step of applying a thermal decomposition treatment comprises applying an oxygen thermal decomposition treatment to convert said patterned layer to a TiO2 hard mask material.

10. A method according to claim 8, wherein the step of applying a thermal decomposition treatment comprises applying an oxygen thermal decomposition treatment to convert said patterned layer to a Ti—Al—O hard mask material.

11. A method according to claim 1, wherein the step of applying a thermal decomposition treatment comprises applying a nitrogen thermal decomposition treatment to convert said patterned layer to a hard mask material.

12. A method according to claim 11, wherein the step of applying a thermal decomposition treatment comprises applying a nitrogen thermal decomposition treatment to convert said patterned layer to a TiN hard mask material.

13. A method according to claim 11, wherein the step of applying a thermal decomposition treatment comprises applying a nitrogen thermal decomposition treatment to convert said patterned layer to an Al—Ti—N hard mask material.

14. A method according to claim 1, wherein the step of applying said photosensitive organic gel layer comprises applying said layer using a spin coating technique.

15. A ferroelectric capacitor device etched according to the hard mask formed according to the method of claim 1.

16. An FeRAM device etched according to the hard mask formed according to the method of claim 1.

17. A hard mask formed according to the method of claim 1.
